(19) United States
(12) Patent Application Publication
(10) Pub. No.: US 2026/0297797 A1
(43) Pub. Date: Oct. 1, 2026

(54) METHODS FOR PREPARING AN INGOT IN AN INGOT PULLER APPARATUS HAVING A HEAT SHIELD DISPOSED BELOW A SIDE HEATER

(71) Applicant: GlobalWafers Co., Ltd., Hsinchu (TW)

(72) Inventors: Sumeet S. Bhagavat, St. Charles, MO (US); Parthiv Daggolu, Creve Coeur, MO (US); Benjamin Michael Meyer, Defiance, MO (US); JaeWoo Ryu, Chesterfield, MO (US)

(21) Appl. No.: 19/703,603

(22) Filed: Jun. 10, 2026

Related U.S. Application Data
(62) Division of application No. 17/096,512, filed on Nov. 12, 2020.

(51) Int. Cl. C30B 15/14; C30B 29/06

(52) U.S. Cl. CPC C30B 15/14; C30B 29/06; Y10T 117/1016

(57) ABSTRACT

Ingot puller apparatus having a heat shield disposed below a side heater and methods for preparing an ingot in such ingot puller apparatus are disclosed. In some embodiments, the side heater is relatively short. The side heater may be fully above a floor of the crucible when the crucible is in its lowest position in the ingot puller.

### CROSS-REFERENCE TO RELATED APPLICATIONS

This application is a Divisional of U.S. patent application Ser. No. 17/096,512, filed Nov. 12, 2020, which is incorporated herein by reference in its entirety.

### FIELD OF THE DISCLOSURE

The field of the disclosure relates to ingot puller apparatus and, in particular, ingot puller apparatus having a heat shield disposed below a side heater.

### BACKGROUND

Some conventional ingot puller apparatus include a relatively long side heater in the ingot puller hotzone. To achieve a desired temperature profile in the melt, insulation is removed toward the bottom of the hotzone. Removal of insulation increases the side heater energy input thereby decreasing thermal efficiency. Further, relatively long heaters may heat the bottom of the crucible and the shaft used to raise the crucible when the crucible is raised during crystal growth further decreasing the energy efficiency of the process.

A need exists for ingot puller apparatus having a hotzone that allows a desirable temperature profile to be achieved while increasing the efficiency of the hotzone and the heating system.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to an ingot puller apparatus for producing a silicon ingot. The ingot puller apparatus includes a crucible for holding a melt of silicon. The crucible has a floor and a sidewall that extends from the floor. The ingot puller apparatus includes a growth chamber for pulling a silicon ingot from the melt along a pull axis. The ingot puller apparatus includes a lift mechanism for raising and lowering the crucible during crystal growth relative to the pull axis. The crucible moves axially between a lowest position in which a charge of silicon is melted to produce the silicon melt, a seed-dip position at which a seed crystal is initially contacted with the melt to pull the silicon ingot from the melt, and a terminal position in which the crucible has been depleted of melt. A side heater is disposed radially outward to the crucible sidewall as the crucible travels from the lowest position to the terminal position. A bottom heater is disposed below the crucible floor. A heat shield is disposed directly below the side heater.

Yet another aspect of the present disclosure is directed to a method for preparing an ingot in an ingot puller apparatus comprising a crucible having a floor and sidewall extending from the floor, a side heater disposed radially outward to the crucible sidewall, and a heat shield disposed directly below the side heater. A melt of silicon is formed in the crucible when the crucible is in a lowest position, the side heater being fully above the floor of the crucible when the crucible is in the lowest position. The melt is contacted with a seed crystal. An ingot is withdrawn from the silicon melt. The crucible is raised as the ingot is withdrawn from the silicon melt, the crucible being in a terminal position when the ingot is separated from the melt.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is an cross-section view of an ingot puller apparatus having a heat shield disposed below a side heater with the crucible in the lowest position;

FIG. 2 is a cross-section view of the ingot puller apparatus during ingot growth;

FIG. 3 is a cross-section view of the ingot puller apparatus with the crucible in a terminal position in which the melt is depleted;

FIG. 4 is a cross-section view of another ingot puller apparatus having a relatively longer side heater and without a heat shield disposed below the side heater;

FIG. 5 is a schematic view of the temperature profile of the melt and side heater of the ingot puller apparatus of FIG. 4; and

FIG. 6 is a schematic view of the temperature profile of the melt and side heater of the ingot puller apparatus of FIGS. 1-3.

Corresponding reference characters indicate corresponding parts throughout the drawings.

### DETAILED DESCRIPTION

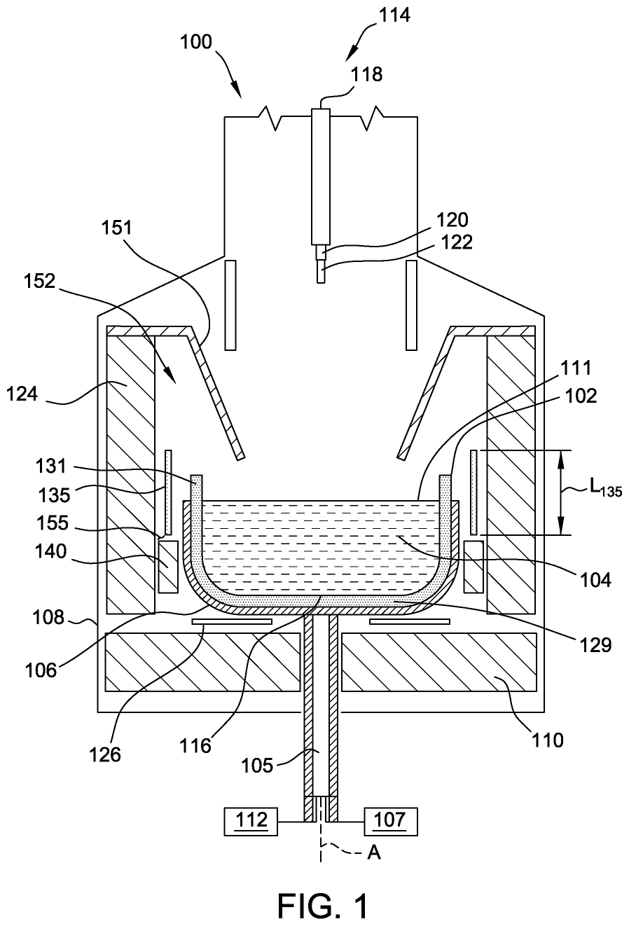

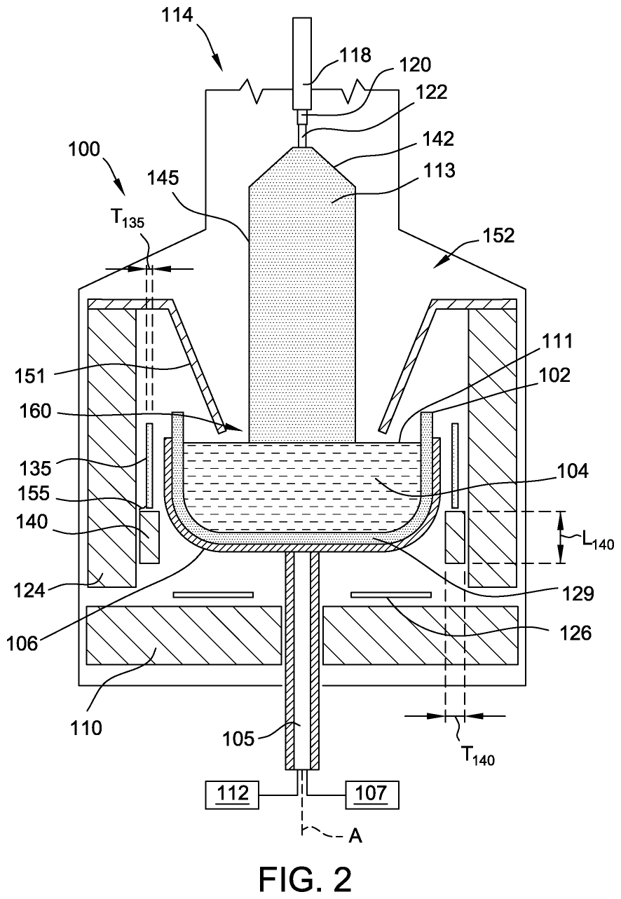

An ingot puller apparatus (or more simply “ingot puller”) is indicated generally at “100” in FIG. 1. The ingot puller apparatus 100 includes a crucible 102 for holding a melt 104 of semiconductor or solar-grade material, such as silicon, supported by a susceptor 106. The ingot puller apparatus 100 includes a crystal puller housing 108 that defines a growth chamber 152 for pulling a silicon ingot 113 (FIG. 2) from the melt 104 along a pull axis A.

The crucible 102 includes a floor 129 and a sidewall 131 that extends upward from the floor 129. The sidewall 131 is generally vertical. The floor 129 includes the curved portion of the crucible 102 that extends below the sidewall 131. The crucible 102 includes a bottom 116 which is the lowest point of the crucible 102 relative to the pull axis A. Within the crucible 102 is a silicon melt 104 having a melt surface 111 (i.e., melt-ingot interface).

The susceptor 106 is supported by a shaft 105. The susceptor 106, crucible 102, shaft 105 and ingot 113 (FIG. 2) have a common longitudinal axis A or “pull axis” A.

A pulling mechanism 114 is provided within the ingot puller apparatus 100 for growing and pulling an ingot 113 from the melt 104. Pulling mechanism 114 includes a pulling cable 118, a seed holder or chuck 120 coupled to one end of the pulling cable 118, and a seed crystal 122 coupled to the seed holder or chuck 120 for initiating crystal growth. One end of the pulling cable 118 is connected to a pulley (not shown) or a drum (not shown), or any other suitable type of lifting mechanism, for example, a shaft, and the other end is connected to the chuck 120 that holds the seed crystal 122. In operation, the seed crystal 122 is lowered to contact the melt 104. The pulling mechanism 114 is operated to cause the seed crystal 122 to rise. This causes a single crystal ingot 113 (FIG. 2) to be pulled from the melt 104.

During heating and crystal pulling, a crucible drive unit 107 (e.g., a motor) rotates the crucible 102 and susceptor 106. A lift mechanism 112 raises and lowers the crucible 102 along the pull axis A during the growth process. For example, as shown in FIG. 1, the crucible may be at a lowest position (near the bottom heater 126) in which a charge of solid polycrystalline silicon previously added to the crucible 102 is melted. Crystal growth commences by contacting the melt 104 with the seed crystal 122 and lifting the seed crystal 122 by the pulling mechanism 114. The crucible 102 may be raised a distance from its lowest position before the melt 104 is contacted with the seed crystal 122 (i.e., raised to a “seed-dip position”).

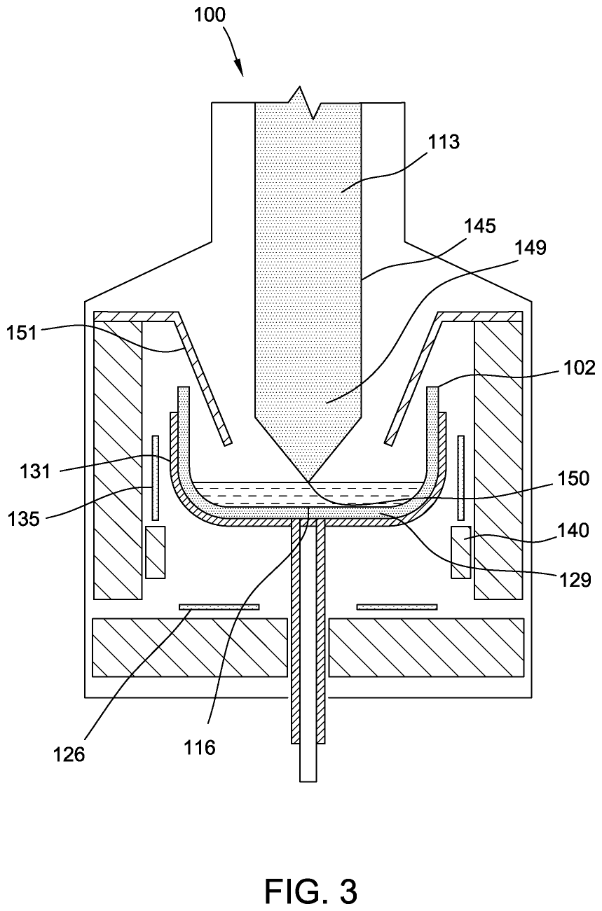

As the ingot grows, the silicon melt 104 is consumed and the height of the melt in the crucible 102 decreases. The crucible 102 and susceptor 106 may be raised to maintain the melt surface 111 at or near the same position relative to the ingot puller apparatus 100. The crucible 102 may move axially between its lowest position shown in FIG. 1 (e.g., at meltdown), to the seed-dip position at which a seed crystal is initially contacted with the melt to pull the silicon ingot from the melt, and a terminal position (FIG. 3) in which the crucible has been depleted of melt. The terminal position of the crucible 102 is above the seed-dip position of the crucible 102 (and lowest position).

A crystal drive unit (not shown) may also rotate the pulling cable 118 and ingot 113 (FIG. 2) in a direction opposite the direction in which the crucible drive unit 107 rotates the crucible 102 (e.g., counter-rotation). In embodiments using iso-rotation, the crystal drive unit may rotate the pulling cable 118 in the same direction in which crucible drive unit 107 rotates the crucible 102. In addition, the crystal drive unit raises and lowers the ingot 113 relative to the melt surface 111 as desired during the growth process.

The ingot puller apparatus 100 may include an inert gas system to introduce and withdraw an inert gas such as argon from the growth chamber 152. The ingot puller apparatus 100 may also include a dopant feed system (not shown) for introducing dopant into the melt 104.

According to the Czochralski single crystal growth process, a quantity of polycrystalline silicon, or polysilicon, is charged to the crucible 102. The semiconductor or solar-grade material that is introduced into the crucible is melted by heat provided from one or more heating elements. The ingot puller apparatus 100 includes bottom insulation 110 and side insulation 124 to retain heat in the puller apparatus. In the illustrated embodiment, the ingot puller apparatus 100 includes a bottom heater 126 disposed below the crucible floor 129. The crucible 102 may be moved to be in relatively close proximity to the bottom heater 126 to melt the polycrystalline charged to the crucible 102.

To form the ingot, the seed crystal 122 is contacted with the surface 111 of the melt 104. The pulling mechanism 114 is operated to pull the seed crystal 122 from the melt 104. Referring now to FIG. 2, the ingot 113 includes a crown portion 142 in which the ingot transitions and tapers outward from the seed crystal 122 to reach a target diameter. The ingot 113 includes a constant diameter portion 145 or cylindrical “main body” of the crystal which is grown by increasing the pull rate. The main body 145 of the ingot 113 has a relatively constant diameter. The ingot 113 includes a tail or end-cone 149 (FIG. 3) in which the ingot tapers in diameter after the main body 145. When the diameter becomes small enough, the ingot 113 is then separated from the melt 104. The ingot 113 has a central longitudinal axis A that extends through the crown portion 142 and a terminal end 150 of the ingot 113.

The ingot puller apparatus 100 includes a side heater 135 and a susceptor 106 that encircles the crucible 102 to maintain the temperature of the melt 104 during crystal growth. The side heater 135 is disposed radially outward to the crucible sidewall 131 as the crucible 102 travels up and down the pull axis A (e.g., from the lowest position to the terminal position). The side heater 135 and bottom heater 126 may be any type of heater that allows the side heater 135 and bottom heater 126 to operate as described herein. In some embodiments, the heaters 135, 126 are resistance heaters. The side heater 135 and bottom heater 126 may be controlled by a control system (not shown) so that the temperature of the melt 104 is controlled throughout the pulling process.

In accordance with embodiments of the present disclosure, the side heater 135 may have a relatively shorter length L₁₃₅ (i.e., height) relative to conventional ingot crystal pullers which may reduce the amount of oxygen taken up in the ingot 113. In some embodiments, the side heater 135 may have a length L₁₃₅ of 500 mm or less, 450 mm or less, 400 mm or less, or 350 mm or less. At least a portion of the side heater 135 is laterally aligned with the sidewall 131 of the crucible 102 as the crucible 102 travels between the crucible lowest position, seed-dip position and the terminal position (e.g., a radius that orthogonally extends outward from the pull axis A is capable of intersecting the sidewall 131 and crucible 102).

The ingot puller apparatus 100 also includes a heat shield 140 that encircles the crucible 102 and susceptor 106 to maintain the temperature of the melt 104 during crystal growth. The heat shield 140 is disposed below the side heater 135 and may be separated from the side heater 135 by a gap 155. In some embodiments, the heat shield 140 is separated from the side heater 135 by no more than about 50 mm or no more than 40 mm (e.g., from 30 mm to about 50 mm). In other embodiments, the heat shield 140 is not separated from the side heater 135 (i.e., the heat shield 140 and side heater 135 are continuous).

In the illustrated embodiment, the heat shield 140 is disposed directly below the side heater 135 (i.e., the side heater 135 and heat shield 140 are aligned when viewed from below or “vertically aligned”). In some embodiments, the heat shield 140 has a length L₁₄₀ (FIG. 2) that is greater than the thickness T₁₄₀ of the heat shield 140. The heat shield 140 may have a thickness T₁₄₀ that is at least the thickness T₁₃₅ of the side heater 135 and, in other embodiments, is at least 1.1 times the thickness T₁₃₅ of the side heater 135, at least 1.25 times the thickness T₁₃₅ of the side heater 135, or at least 1.5 times the thickness T₁₃₅ of the side heater 135 (e.g., from 1.0 to 2.0 times the thickness T₁₃₅ of the side heater 135.). The heat shield 140 may be radially disposed relative to the side heater 135 such that a portion of the heat shield 140 overlaps each side of the side heater 135 (i.e., when viewed from above a first portion of the heat shield 140 is radially inward to the side heater 135 and a second portion of the heat shield 140 is radially outward to the side heater 135).

The heat shield 140 may generally be made of any material that reduces cooling of the bottom portion of the side heater 135. The heat shield may include insulation or reflective material. The heat shield may be layered. In embodiments in which the heat shield is made of insulation, the insulation may be capped with graphite to reduce risk of zero dislocation in the ingot. In some embodiments, the heat shield may include a graphite shell with molybdenum sheets being disposed within the shell to block radiation.

The ingot puller apparatus 100 may include a second heat shield 151 (e.g., with the first heat shield 140 being a “lower” heat shield and the second heat shield 151 being an “upper heat shield”). The second heat shield 151 may shroud the ingot 113 such that the ingot passes through an opening 160 formed by the heat shield 151. The heat shield 151 and may be disposed within the crucible 102 during crystal growth (e.g., as shown in the terminal position of the crucible 102 as shown in FIG. 3).

The crucible 102 is shown in its lowest position in FIG. 1. In the illustrated embodiment, when the crucible 102 is in its lowest position, the side heater 135 is fully above the floor 129 of the crucible 102. For example, the distance between the bottom 116 of the crucible 102 and the side heater 135 (i.e., the distance to the bottom of the side heater 135) may be at least about 25 mm or at least about 50 mm. The distance between the bottom 116 of the crucible 102 and the top of the side heater 135 may be at least about 75 mm or at least about 100 mm. At least a portion of the heat shield 140 is above the bottom 116 of the crucible 102. At least a portion of the heat shield 140 is also below at least a portion of the floor 129 of the crucible 102.

The crucible 102 is shown in its terminal position in FIG. 3. In the illustrated embodiment, when the crucible 102 is in the terminal position, the heat shield 140 is fully below the floor 129 of the crucible 102. The heat shield 140 is also fully below the susceptor 106 when the crucible 102 is in the terminal position.

Ingot puller apparatus of the present disclosure have several advantages over conventional ingot puller apparatus. In embodiments in which the ingot puller apparatus includes a relatively short side heater (e.g., when the side heater has a length of 500 mm or less, 450 mm or less, 400 mm or less or 350 mm or less and/or the side heater is fully above the floor of the crucible when the crucible is in its lowest position), the heat from the side heater is directed to the crucible and susceptor directly rather than some energy being directed toward the shaft and bottom insulation as the crucible is raised during ingot growth. This results in more efficient energy usage and moves the melt hotspot upward from the melt-crucible interface. This allows more insulation to be added to move the hotspot down and maintain the same temperature profile with less energy and with less leaks toward the bottom of the hotzone thereby improving efficiency. During growth of the late body of the ingot (i.e., the portion of the constant diameter portion toward the end-cone which is grown when the crucible is relatively high in the puller apparatus), the temperature range of the crucible wall may be wider relatively to use of longer heaters which allows the interstitial oxygen of the late body to be reduced.

In embodiments in which a heat shield is disposed below the side heater, the heat shield reduces cooling of the lower portion of the side heater because the heat shield reduces exposure to the relatively cooler components toward the bottom of the hotzone. This reduces the energy needed for the heater to achieve its desired temperature and increases the energy efficiency of the hotzone.

### EXAMPLES

The processes of the present disclosure are further illustrated by the following Examples. These Examples should not be viewed in a limiting sense.

### Example 1: Use of a Hotzone With a 525 mm Heater vs a Hotzone With a 325 mm Heater With a Heat Shield Disposed Below the Heater

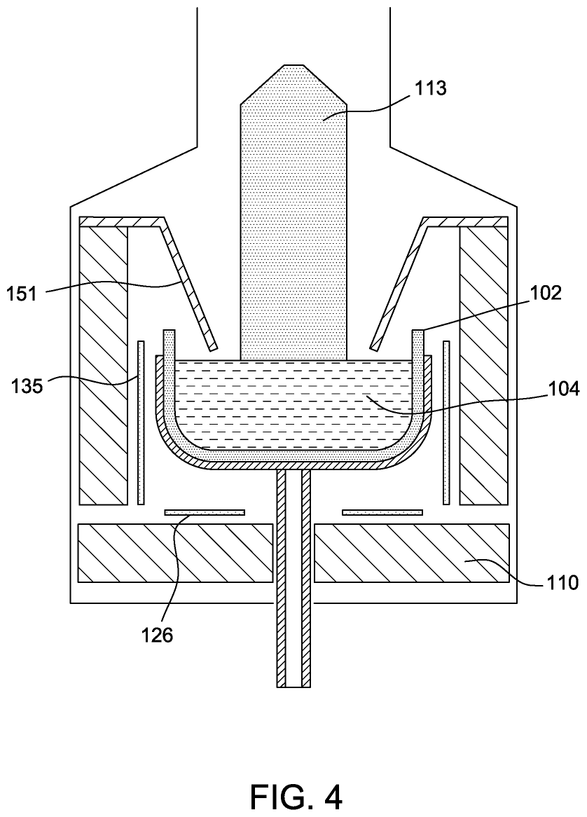

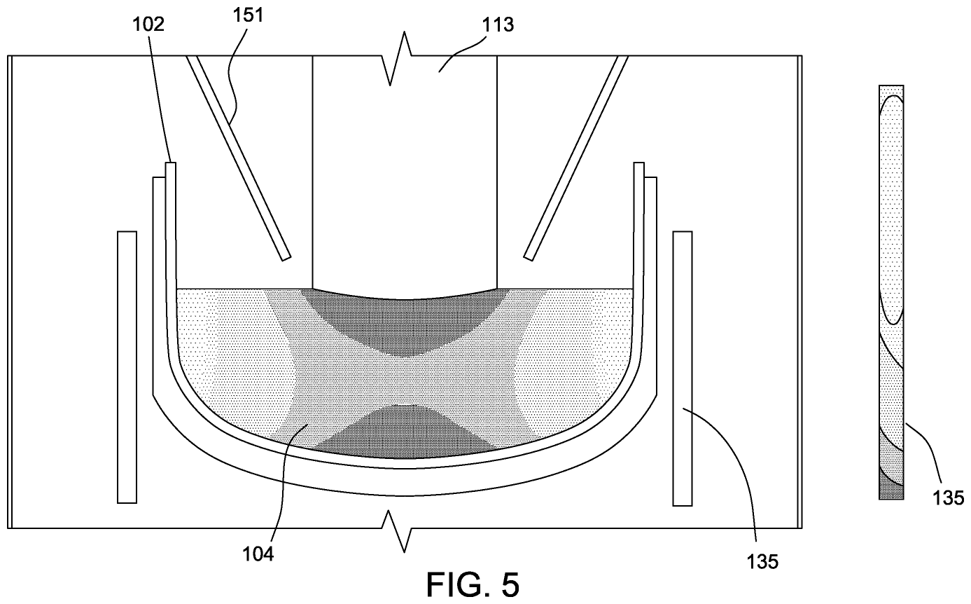

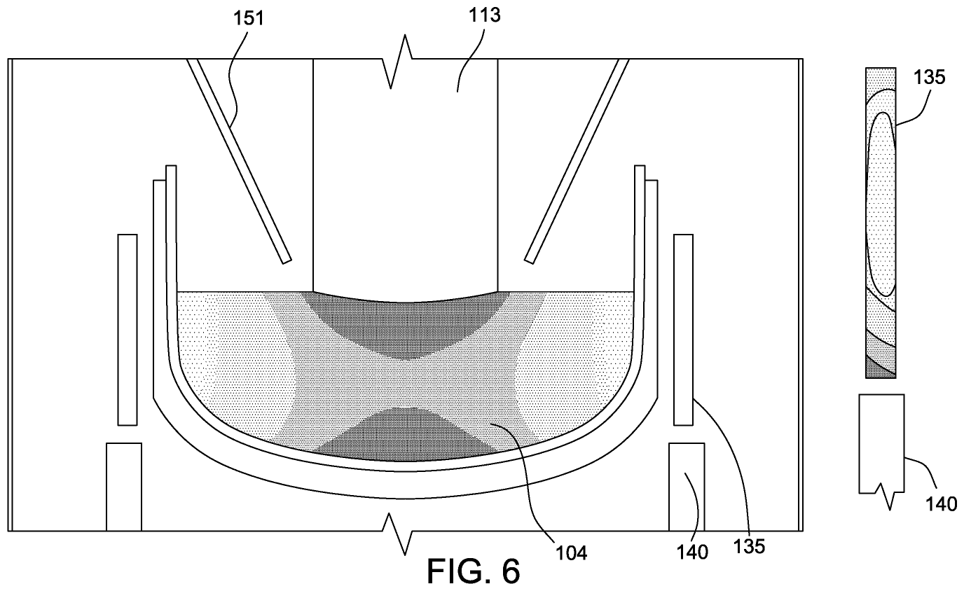

FIG. 5 shows the temperature profile of the hotzone configuration of the ingot puller apparatus of FIG. 4 (cooler portions of the melt and heater are shown with darker stippling in FIGS. 5 and 6). The hotzone of FIG. 4 included a side heater 135 with a length of 525 mm and did not include a heat shield below the side heater. The hotzone also included a portion of the insulation removed toward the bottom of the hotzone to achieve the desired temperature profile. The side heater of FIG. 4 was operated at 103 kW and the bottom heater was operated at 5 kW (108 kW total heat input). The temperature profile of FIG. 5 is desirable as the melt hotspot is at the melt-crucible interface. As shown in the temperature profile of the side heater which is to the right of FIG. 5, the side heater was relatively cool toward the lower portions of the heater because of the reduced insulation.

FIG. 6 shows the temperature profile of the hotzone configuration of the ingot puller apparatus of FIGS. 1-3 in which a relatively shorter side heater 135 of 325 mm in length was used (i.e., 200 mm less than the side heater of FIG. 4). The hotzone included a heat shield 140 disposed below the side heater 135. The hotzone included an amount of insulation (about 1 inch) removed toward the bottom of the ingot puller apparatus relative to the hotzone of FIG. 4. The side heater 135 was operated at 59 kW and the bottom heater was operated at 5 kW (64 kW total heat input).

As shown in FIG. 6, the melt had substantially the same desirable temperature profile as the hotzone of FIG. 4 (which is shown in FIG. 5) but the ingot puller apparatus was operated with 44 kW less power input (i.e., 41% less).

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a”, “an”, “the” and “said” are intended to mean that there are one or more of the elements. The terms “comprising,” “including,” “containing” and “having” are intended to be inclusive and mean that there may be additional elements other than the listed elements. The use of terms indicating a particular orientation (e.g., “top”, “bottom”, “side”, etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A method for preparing an ingot in an ingot puller apparatus comprising a crucible having a floor and sidewall extending from the floor, a side heater disposed radially outward to the crucible sidewall, and a heat shield disposed directly below the side heater, the method comprising:
forming a melt of silicon in the crucible when the crucible is in a lowest position, the side heater being fully above the floor of the crucible when the crucible is in the lowest position;
contacting the melt with a seed crystal;
withdrawing an ingot from the silicon melt; and
raising the crucible as the ingot is withdrawn from the silicon melt, the crucible being in a terminal position when the ingot is separated from the melt.

2. The method as set forth in claim 1 wherein the heat shield is disposed directly below the side heater.

3. The method as set forth in claim 1 wherein at least a portion of the heat shield is above a bottom of the crucible when the crucible is in the lowest position.

4. The method as set forth in claim 1 wherein at least a portion of the heat shield is below at least a portion of the floor of the crucible when the crucible is in the lowest position.

5. The method as set forth in claim 1 wherein the heat shield is fully below the floor of the crucible when the crucible is raised to the terminal position.

6. The method as set forth in claim 1 wherein the side heater has a length of 500 mm or less.

7. The method as set forth in claim 1 wherein the side heater has a length of 450 mm or less.

8. The method as set forth in claim 1 wherein the side heater has a length of 350 mm or less.
